(19) United States
(12) Patent Application Publication
(10) Pub. No.: US 2025/0259396 A1
(43) Pub. Date: Aug. 14, 2025

(54) GEOMETRY-INDEPENDENT DESIGN WITH NATIVE MESH SURFACE FORMATION AND VARIABLE COMPONENT-CONFORMITY

(71) Applicant: mign, Inc., Charlotte, NC (US)

(72) Inventors: Elliott Dix, Charlotte, NC (US); Li Chen, Zurich (CH)

(21) Appl. No.: 19/052,217

(22) Filed: Feb. 12, 2025

Related U.S. Application Data
(60) Provisional application No. 63/553,133, filed on Feb. 13, 2024.

(51) Int. Cl. G06T 17/20; G06F 30/20; G06T 17/30

(52) U.S. Cl. CPC G06T 17/205; G06F 30/20; G06T 17/30; G06T 2210/41

(57) ABSTRACT

A configuration enables variable component conformity to native mesh. Surface position and parametric adjustment parameters are received for an image mesh and projection parameters are identified for a component. Variable component conformity is initiated for RGB variables for object vertices. A control point location is placed on the image mesh and is paired with a centroid of a surface and equated to a first and second coordinate systems. Each coordinate system retains component vertices locations as a first set of coordinates. For each vertex, an RGB value is identified. Using the RGB value, a hybrid vertex location is calculated by equating coordinates from the first coordinate system with the coordinates from the second coordinate system and adjusting an offset value. A new set of coordinates is generated in the second coordinate system and mapped vertices are generated from the hybrid vertex location to generate an output for the component.

### CROSS REFERENCE TO RELATED APPLICATIONS

This application claims a benefit of, and priority to, U.S. Patent Application No. 63/553,133, filed Feb. 13, 2024, the contents of which is incorporated by reference in its entirety.

### TECHNICAL FIELD

The disclosure generally relates to the field of image processing, and more particularly, native surface extrapolation.

### BACKGROUND

Medical wearables provide support for a body or parts of a body to properly align to help correct medical conditions. Correction of medical conditions may include spinal curvature disorders or resetting of bones due to injury. Current digital brace technology is imprecise and is not customizable to fit the specific contours of a body or body part of an individual that requires wearable assistance. Custom braces may be manufactured to try to match the contours of a body or body part. These braces, however, are time consuming to design for a specific individual and costly to manufacture as they are only applicable to a specific individual and cannot be applied more widely to others.

### BRIEF DESCRIPTION OF DRAWINGS

The disclosed embodiments have other advantages and features which will be more readily apparent from the detailed description, the appended claims, and the accompanying figures (or drawings). A brief introduction of the figures is below.

FIG. 1A illustrates one embodiment of an example environment to capture, manipulate and manufacture a wearable in accordance with an embodiment.

FIGS. 1B and 1C illustrate an example process of a selective surface and variable component-conformity design system in accordance with an embodiment.

FIG. 2 illustrates an example process for creating profile curves for a product design in accordance with an embodiment.

FIGS. 3A through 3C illustrate an example process for selecting native mesh faces, pairing control points to mesh faces, and creating a profile curve with added control points on a mesh in accordance with an embodiment.

FIGS. 4A through 4D illustrate an example process for calculating a curve fit via control point distance to mesh face in accordance with an embodiment.

FIG. 5 illustrates an example process for manipulating a profile curve in accordance with an embodiment.

FIG. 6 illustrates an example process for switching line segment behavior in accordance with an embodiment.

FIG. 7 illustrates an example process for inserting points into an existing curve in accordance with an embodiment.

FIG. 8 illustrates an example effect of a switch line function on indicated line segment and a point being inserted in the line segment in accordance with an embodiment.

FIG. 9 illustrates an example process for removing points from an existing curve in accordance with an embodiment.

FIG. 10 illustrates an example process for component contouring for mass customization in accordance with an embodiment.

FIG. 11 illustrates an example process for preparing component to function within component variable conformity surface mapping in accordance with an embodiment.

FIGS. 12A through 12C illustrate an example process for creating a NURBS surface that conforms onto a native mesh in accordance with an embodiment.

FIGS. 13A through 13F illustrate an example process for enabling uniform and variable component conformity to native mesh via NURBS surfaces and coordinate transformations in accordance with an embodiment.

FIGS. 14A through 14D illustrate an example process for surface parameter control in accordance with an embodiment.

FIGS. 15A and 15B illustrate an example process for product realization via native mesh surface formation and extrusion via profile curve driven splitting of the native mesh in accordance with an embodiment.

FIGS. 16A and 16B illustrate examples of split body extrusion parameters in accordance with an embodiment.

FIG. 17 illustrates an example machine, e.g., computer system, in accordance with an embodiment.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

### Configuration Overview

Disclosed is a system and process for geometry independent product design through native mesh surface selection and variable component conformity in an image processing system in accordance with an embodiment. The process may start with importation of a three-dimensional scan of a human anatomy from a scan device. STL, PLY or OBJ formats from scan devices are accepted. The process transforms the input scan into watertight mesh, which may include mesh repair, orientation, and/or scaling. The process manipulates the mesh geometry. This may include global mesh manipulation whereby mesh regions shift, bend and/or scale relative to one another, or local mesh manipulation whereby specific vertex and face clusters are deformed in user-controlled patterns. The original and manipulated mesh are retained for comparative analysis via a set of visualization and verification tools to ensure conformity with design goals. Collectively these tools take initial, digital input of the human anatomy and manipulate it to what may be an ideal alignment of the anatomy. This creates a modified treatment mesh.

The treatment mesh interacts with a profile curve tool, a component placement tool, and a pattern tool. The profile curve tool outputs a set of one (1) or more profile curves, which create an outline of the product along the topography of the treatment mesh. The profile curves create the perimeter of the product itself (e.g., a brace) and interior features intended to lightweight (cutouts) or reinforce based on extrusion parameters. The component placement tool generates an output to component layout and with prepared bodies. The tool contours traditionally (parametric computer aided design (CAD)) designed geometry (component) to the unique patient topography while preserving the dimensions of key, user-defined regions. The pattern tool generates an output to the pattern layout. The pattern layout replaces neutral (unused space) with a geographic pattern (versus a solid shell) to create lightweight, personalized, and optimized mechanical properties of the product. The output of the profile curve tool is input into a split function. The split function uses the profile curves to separate the treatment mesh into a set of surface bodies. The surface bodies output by the split function are input into design extrusion tools that extrude, smooth, and fillet the extrusion to create the product base. The resultant product base is input into the Boolean chain along with the output of the component layout and preparation and the pattern layout. The Boolean chain unions, intersects, and subtracts these input bodies and outputs a unitary product and can be stored or export as a final part output.

### Example Environment

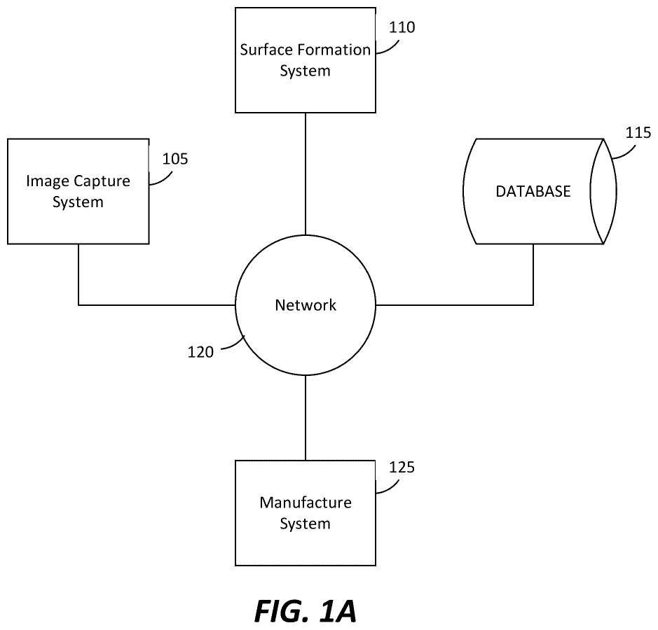

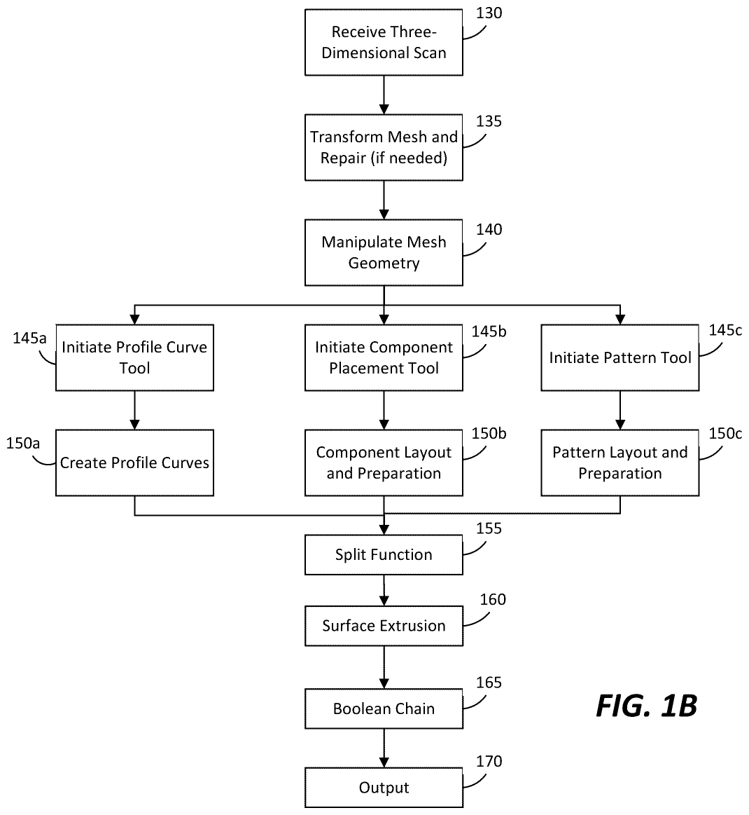

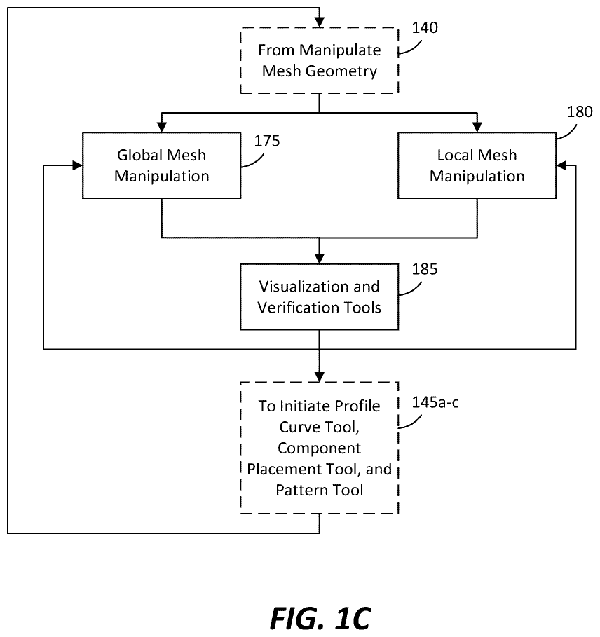

Figure (FIG. 1A illustrates one embodiment of an example environment to capture, manipulate and manufacture a wearable in accordance with an embodiment. The environment includes an image capture system 105, a surface extrapolation system 110, a database 115 and manufacture system 125. The image capture system 105 is configured to capture an image, e.g., of a body or body part. The image capture system 105 may be a camera system that captures two-dimensional (2D) or three-dimensional images (3D). In one embodiment, the environment is configured to execute with three-dimensional images.

The surface formation system 110 is configured to analyze a surface area of the three-dimensional image and extrapolate outside the surface boundary as described herein. The surface formation system also is configured to generate dimensioned images for a device that are adjusted to the contours of a processed boundary surface as described herein.

The database 115 is configured to store images from the image capture system 105 and processed images from the surface formation system 110. The manufacture system 125 is configured to manufacture a device corresponding to the generated dimensioned images for a device. The manufacture system 125 may be a three-dimensional printing system.

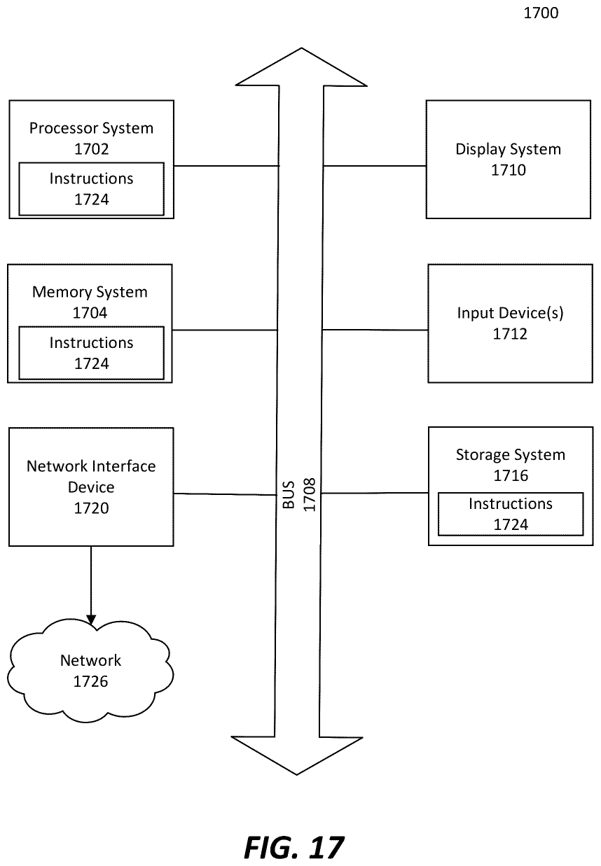

The image capture system 105, the surface formation system 110, the database 115, and the manufacture system are machines. The machines may be computer systems. Each computer system 105, 110, 115, 125 may have some or all of the components of a computer system as further described with FIG. 17.

### Operational Overview

The surface formation system 110 includes algorithms described in FIGS. 1B through 16B that may be executed in a computer system. The computer system may be configured with some, or all, of the components as described with FIG. 17. When executed, the algorithms structure the computer system to be a computer purposed to execute as described.

Referring initially to FIGS. 1B and 1C, illustrated is an example process of a surface formation system in accordance with an embodiment. Referring first to FIG. 1A, the process receives 130 a three-dimensional image scan, e.g., from the image capture system 105 and/or the database 115. The three-dimensional scan may correspond to a specific individual or body part (or portion) of an individual. The scan may be received and/or converted to an image mesh as further described herein. By way of example, the mesh may be a discretization of a geometric domain into small simple shapes, such as triangle or quadrilaterals in 2D and tetrahedral or hexahedra in 3D. The process transforms (e.g., rotates and/or scales) 135 the mesh via translation, scale, and/or rotation and repairs it, if necessary. The process manipulates 140 the mesh geometry as further described in FIG. 1C.

Referring to FIG. 1C, the process manipulates 175 the mesh globally via large regional scaling, rotation, and translation, and may manipulate 180 the mesh locally via clustered vertex deformation. The manipulated mesh may be stored in the database 115. The manipulated mesh and original input mesh may be input 185 into visualization and verification tools to determine manipulated mesh conformance to design standards. The conformance process ensures consistency of quality and accuracy of digital images to properly reproduce source records to meet objective performance attributes. The output from the tools may be iteratively re-inserted into global and local mesh manipulation tools until the output of visualization and verification is in conformance is achieved 175, 180.

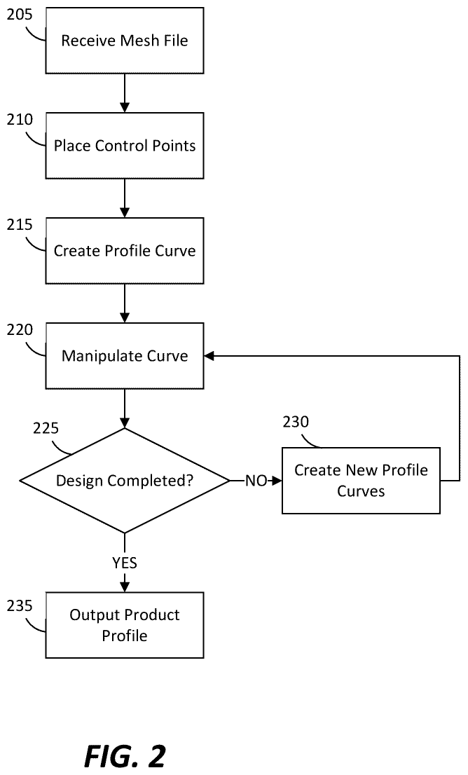

Turning back to FIG. 1B, the process initiates a profile curve tool 145a, component placement tool 145b, and pattern tool 145c. The output from the profile curve tool 145a creates 150a profile curves. A profile curve is a closed curve of three or more user-manipulated control points and non-manipulable reference points that is applied to a surface, e.g., an anatomy of a body or body part (generally, anatomy). Curves are used to design anatomy specific surfaces that are manipulated later in the process to become extruded bodies. Their function is to create the primary outline (or outlines) of product (or device) bodies, window/cutout features within the product, and/or regions of reinforcement. A process for generation of profile curves is further described with FIG. 2.

The output from the component placement tool 145b generates 150b a globally oriented component layout, where the functional geometric features of the device are placed at the user specified locations on the subject mesh and prepared for a Boolean chain. The output from the pattern tool 145c generates 150c a globally oriented pattern layout prepared for the Boolean chain. The profile curves components are input into a split function 155. The output of the split function is a native mesh separated into surface bodies along the path of profile curves. The native mesh is derived from the original image data and will define the vertices, edges, and faces of the three-dimensional (3D) for the anatomical part. In addition, user-selected surface bodies are input into the surface extrusion process 160 to create a product shell of controlled thickness. The process generates 165 a Boolean chain of the individually generated outputs of the tools to generate an output 170 that corresponds to a final part (or device) file composed extruded bodies 180, components 150b, and patterns 150c. The final part (or device) file may be used by the manufacturing system 125 to manufacture the part (e.g., three-dimensional print) that is highly customized to an individual body or body part.

### Example Product Design Workflow

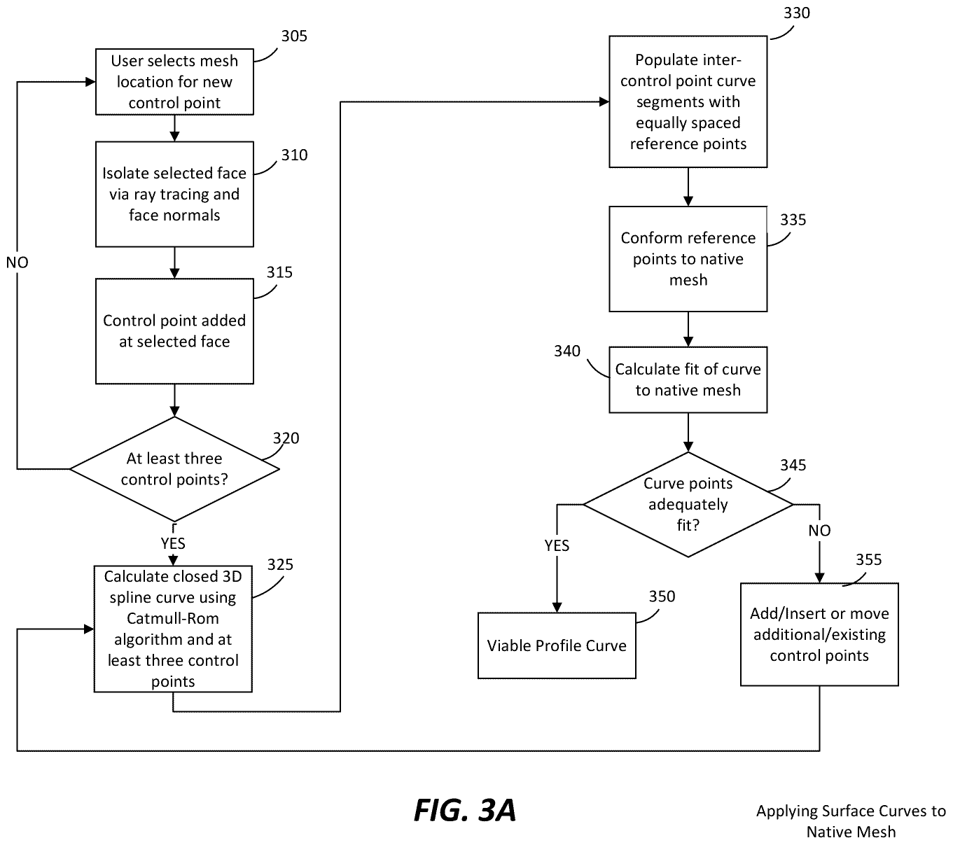

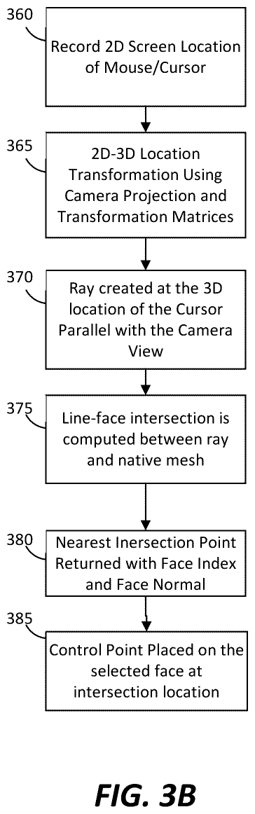

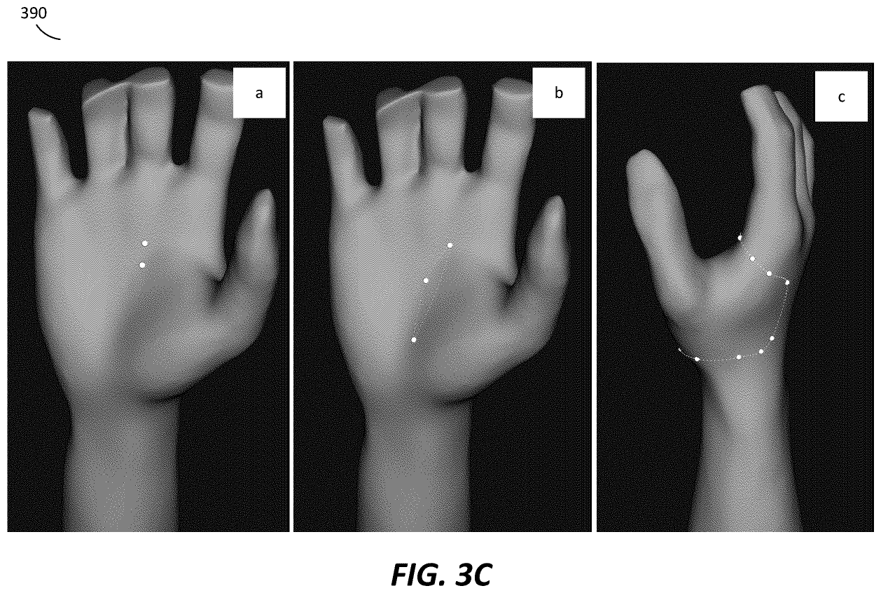

FIG. 2 illustrates an example process for creating profile curves for a product design in accordance with an embodiment. The process receives 205 a mesh file, e.g., from the database 115. The mesh file may be in a format that may be rendered on a screen of a computer system, e.g., computing system 1700. The mesh may correspond to the image captured by the image capture system 105. The process places 210 a control point on the mesh. The control point may be placed, for example, through user input by a mesh-face selection process as described with FIGS. 3A-3C.

FIG. 3A illustrates an example process for adding control points to an image in accordance with an embodiment. The process receives 305 selections of a location on the native image mesh. The process determines 310 a control point location by ray tracing a selected face along a normal. FIG. 3B illustrates the ray tracing process by which control point location on the mesh is calculated. Specifically, the process records 360 a two-dimensional (2D) screen location of a cursor (e.g., mouse cursor) from a computer screen. The process generates 365 a 2D to 3D location transformation using camera projection and transformation matrices. The process creates 370 a ray at the 3D location of the cursor that is parallel with the camera view. The process computes 375 a line-face intersection between the ray and native mesh. The process returns 380 a nearest intersection point with a face index and a face normal. The process places the control point 385 on the selected face at the location of intersection.

Referring back to FIG. 3A, the process determines 320 whether there are at least three control points. If there are not at least three control points the process looks to receive another selection of a location on the native image mesh. If at least three control points have been received, the process calculates a 325 3D spline curve on native mesh using, for example, a Catmull-Rom Algorithm. The spline curve may be a piecewise polynomial (parametric) curve that can be used to design and control the shape of complex curves and surfaces. The 3D spline curve may be a mathematical model that represents continuous smooth curves with control points and polynomial interpolation in image (or graphic) processing systems. The process populates 330 the curve with equally spaced points that are not the user-manipulable control points but are the constituent points of the 3D spline and individually paired to mesh faces to ensure global curve tangency. A mesh face may be a surface like polygon created by grouping vertices together. The faces form the structure of the mesh.

Turning back to FIG. 2, the process creates 215 a profile curve after 3 control points have been added to the mesh, which is further described below. The profile curve is manipulated 220. For example, the user may add or remove points, move point locations, or change line segment behavior on the mesh image. FIG. 3C illustrates control Points (large white circles) and auto-populated reference points (smaller circles) on a mesh image. FIG. 3C (a) illustrates two control points rendered for a mesh file prior or curve creation.

Referring back to FIG. 3A, the process conforms 335 the profile curve to the native mesh. The process determines 340 whether curve points adequately fit to the mesh. If they do not adequately fit, the process adds (or inserts) 355 additional control points as outlined above. If they do adequately fit, the process generates 350 a viable profile curve that may be saved in the database 115.

FIG. 3C (b) illustrates the addition of a third point to the original image in FIG. 3C (a) to create a profile curve. Auto-populated spline reference points are equally spaced a pre-determined amount and will increase in count to preserve spacing within lengthening profile curves as shown in FIG. 3C (c). FIG. 3C (c) illustrates a potential result of 220 profile curve manipulation whereby the control points and profile curve form the user-specified shape.

Turning back to FIG. 2, the process determines 225 whether the design is completed. If the design is not completed the process enables creation 230 of new profile curves that undergo profile manipulation 220. If the design is completed the process outputs 235 a product profile. The product profile and subsequent processes outlined below may be used by the manufacturing system 125 for manufacturing of the part (e.g., three-dimensional print) that is highly customized to an individual body or body part.

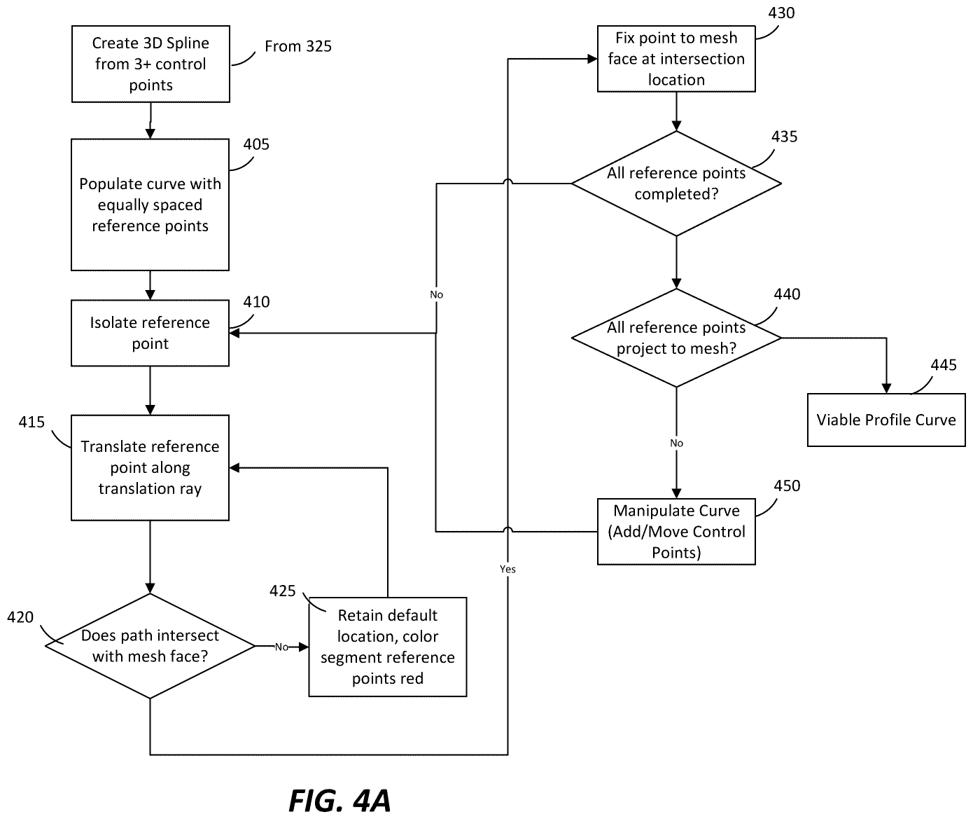

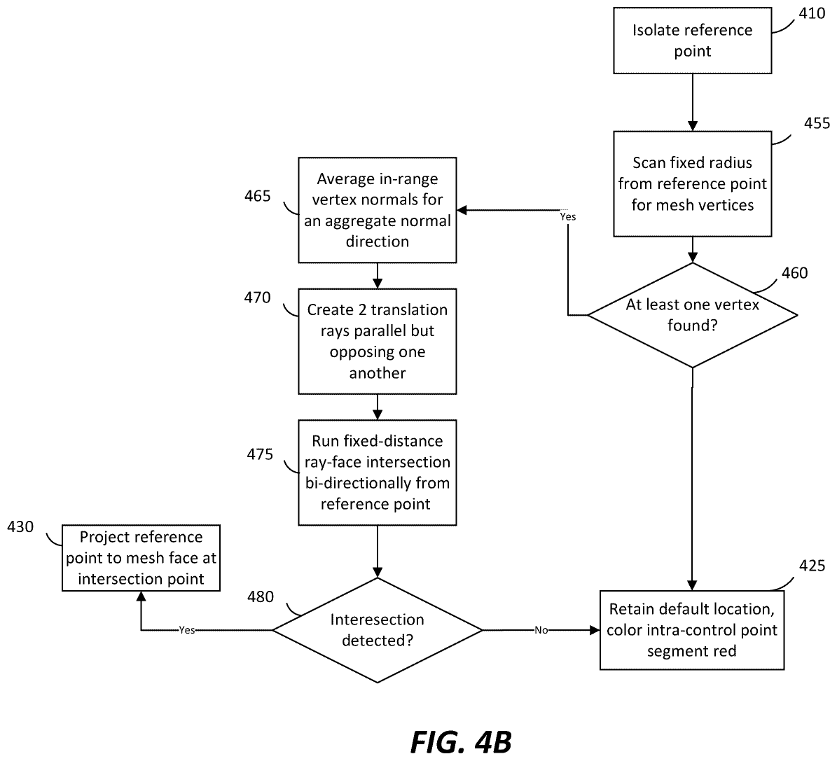

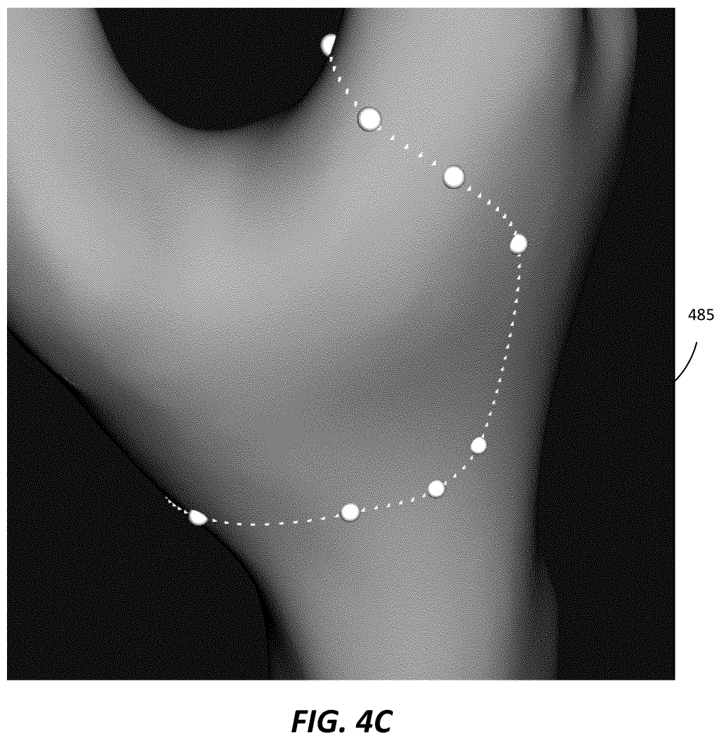

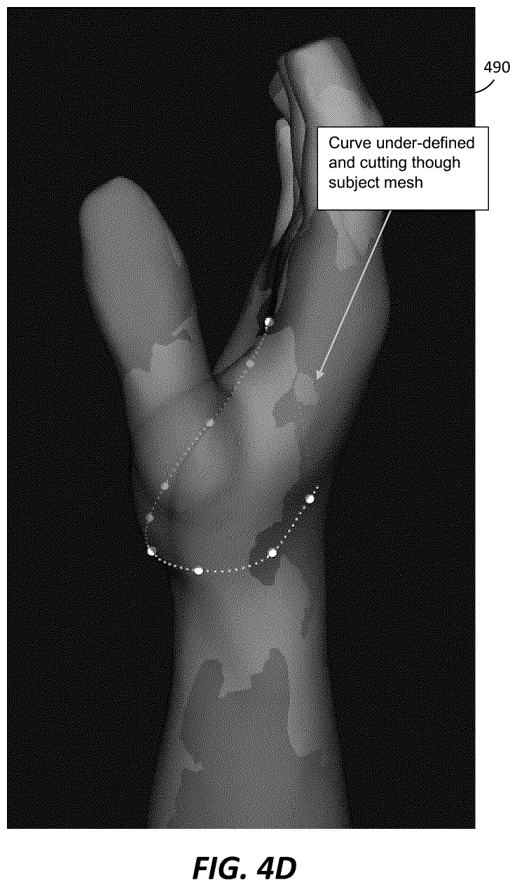

FIGS. 4A through 4C illustrate an example process for conforming profile curves to the mesh and calculating curve fit via control point distance to mesh face in accordance with an embodiment. Turning first to FIG. 4A, the process receives 325 a 3D spline curve from 3 or more control points. The spline is populated 405 with interpolated reference points equally spaced a pre-determined distance. Beginning with the first reference point 410 the process calculates the translation ray 415 and determines 420 if ray-face intersections are present. If the process returns negative for a face-ray intersection 420, the segment of interpolated reference points is colored red to indicate error. If the process returns positive for face-ray intersection, the point is translated to the intersection location 430.

FIG. 4B further details the conformance of interpolated points to the mesh by calculating translation rays. The process scans 455 from the isolated reference point 410 a fixed radius for mesh vertices and retains vertex normal vector. If at least one vertex is found 460, the process calculates the average normal direction of all in-range vertices. The process creates 2 translation rays 470 from the average normal, co-linear but opposite in direction. The process calculates ray-face intersections 475 from the original interpolated reference point location in both directions. If the process detects an intersection 480, the point is translated 430 along the ray to the nearest intersection and retains a default characteristic, e.g. color.

Turning back to FIG. 4A, the process will determine 435 if all translation rays for reference points have been calculated. If additional points remain, the calculation repeats at 410 with the next sequential point. The process then determines if all interpolated points have been projected to mesh-ray intersection points 440, indicated by segment color changes. If some reference points fail to conform to the mesh via translation rays, users manipulate the curve, e.g. point movement, addition, deletion, until the translation succeeds and outputs a 445 viable profile curve.

FIG. 4C illustrates an image mesh 485 with control points (large circles) and interpolated reference points (smaller circles). Reference points are equally spaced a pre-determined amount and will increase in count as the curve lengthens. FIG. 4D illustrates a mesh 490 in which when the mathematical and logical sequence of the curve fit from FIGS. 4A-4B is followed and one or more interpolated points failed to translate to a face intersection, indicated by a line segment color change (red) that informs the user of a need to alter the design (see arrow showing under defined curve segment that cuts through the subject mesh as shown from the distance between the last and first large circles along the curve).

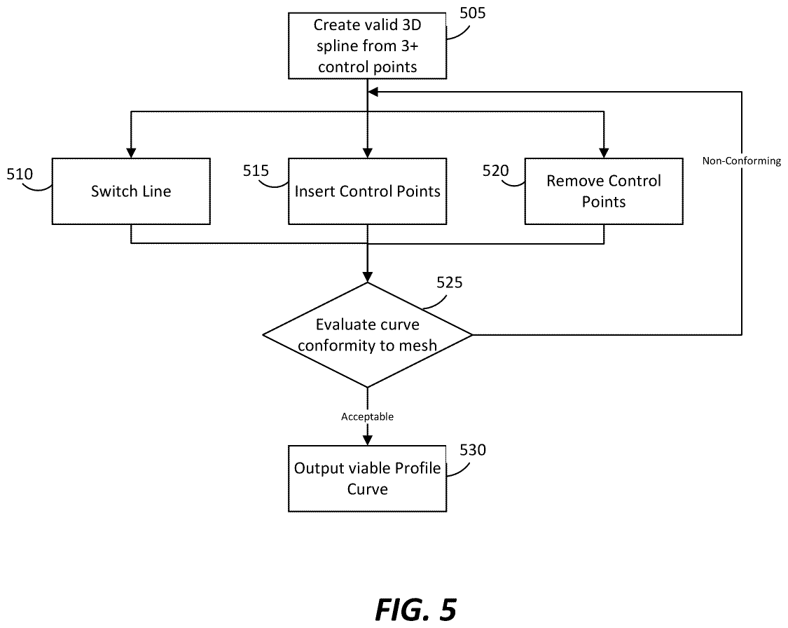

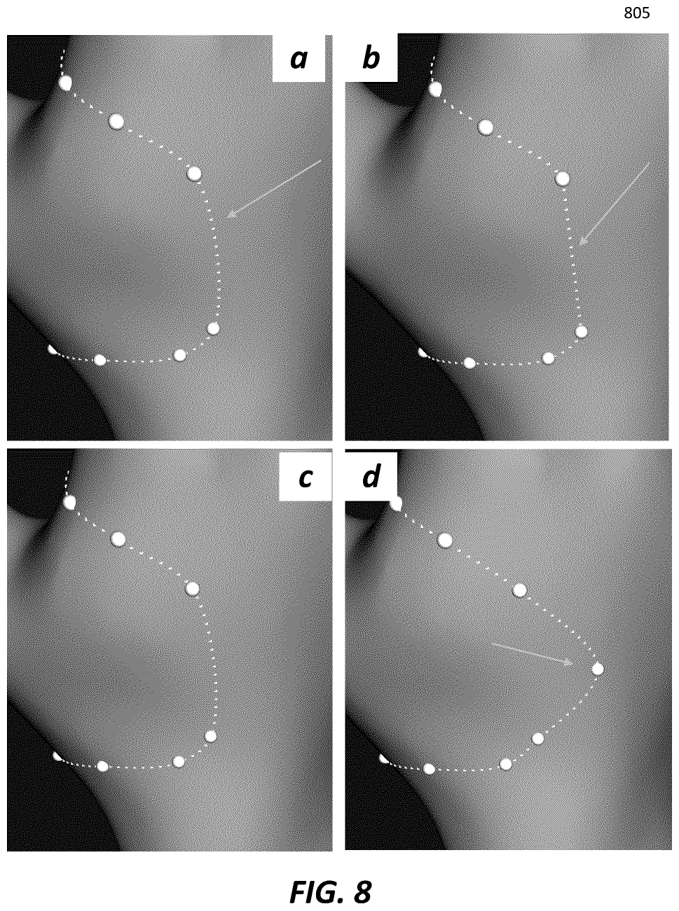

FIG. 5 illustrates an example process for manipulating a profile curve in accordance with an embodiment. The process creates 505 a 3D spline curve on the image mesh. Using the spline curve, the process inserts 515 additional control points onto the curve on the image mesh. It also may switch 510 line segment behavior and may remove 520 control points from the profile curve on the image mesh. FIGS. 8 (a) to 8 (d) are image meshes 805 showing a switch line and addition/insertion of a point. FIGS. 8 (a) and (b) illustrate a switch line process in which an arrow in (a) points to a curvature that is switched to a straight line in (b). FIG. 8 (c) and (d) illustrate the addition/insertion of a point into an existing line segment as shown by an arrow. The process of switching lines and inserting points are further described below.

Returning back to FIG. 5, the process iteratively evaluates 525 the profile curve for viability as a result of each manipulation. Viability has two criteria: 3 or more control points constitute the curve and the interpolated points all conform to the mesh via translation rays as outlined in FIG. 4A through FIG. 4D. If the profile is not viable, the process returns to further manipulate the mesh through switching lines 510, inserting control points 515, removing points and/or moving control points 520 on the image mesh within the spline curve. If the profile is viable the process outputs 530 a viable profile curve. This output may be stored in the database 115.

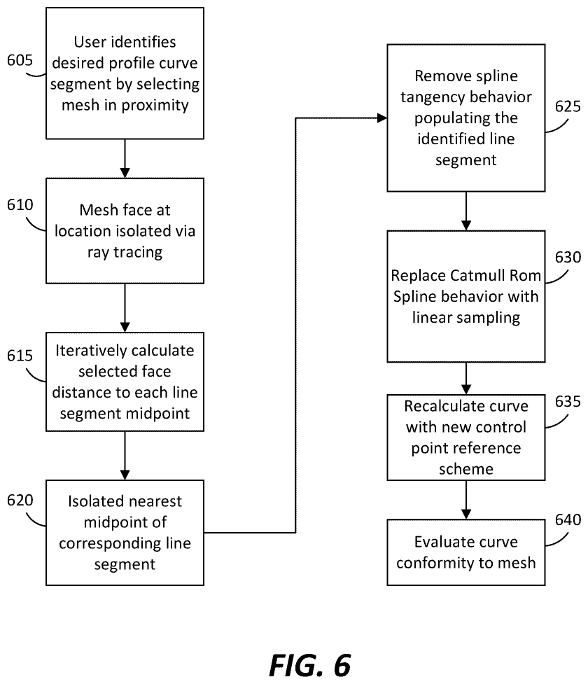

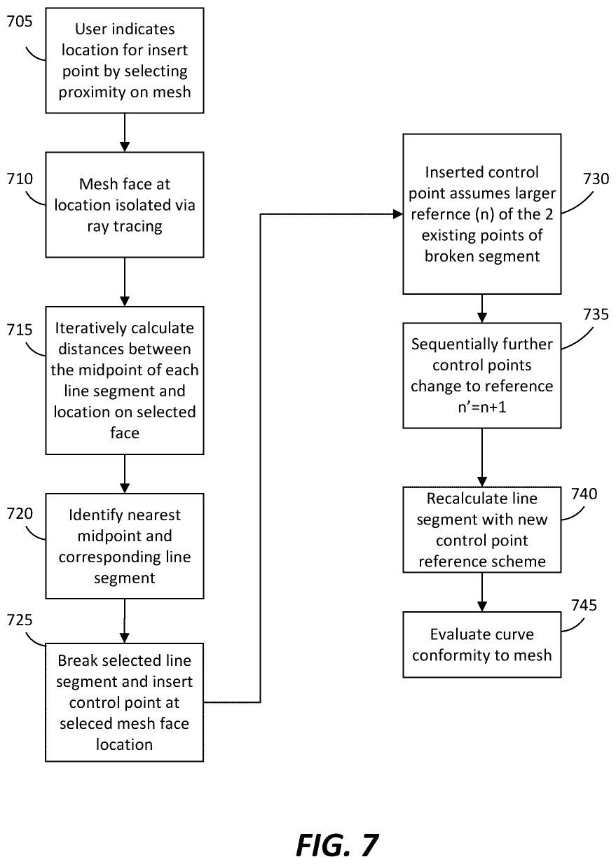

FIG. 6 illustrates an example process for switch line segment behavior in accordance with an embodiment, a FIG. 7 illustrates an example process for inserting points into an existing curve in accordance with an embodiment. FIGS. 6 and 7 may be further illustrated through FIG. 8. As previously noted, FIG. 8 illustrates images 805 with an example effect of a switch line function on indicated line segment ((a) and (b)) and a point being inserted in the line segment ((c) and (d)) in accordance with an embodiment. Point removal is illustrated as the reverse of point insertion shown in FIG. 8 (c and d).

Turning to FIG. 6, a process identifies 605 a desired profile curve segmentation, for example, by selection of a visible line segment (defined as the region of a profile curve between two control points) of a mesh using a control device (e.g., mouse or trackpad) pointer. A ray trace is applied 610 to the viewing angle to determine the mesh face at the user indicated location, for example, in a manner similar to that outlined in FIG. 3B above. The process iteratively calculates 615 the selected mesh face distance to each line segment midpoint of the profile curve(s) on the mesh. The midpoint of a line segment corresponds to the median auto-populated point of that segment (not manipulable by the user). The process identifies 620 the line segment with the nearest midpoint to the selected mesh face and removes 625 the spline tangency calculation between the endpoints of the line segment (e.g. the bounding control points). The process performs 630 a linear sampling for points populating the selected line segment. The spline curve is recalculated 635 with the new control point reference scheme and the curve is evaluated 640 for mesh fit, for example, as described above with FIGS. 4A-4C. The same process can be performed to switch a line segment with linear behavior back to the default tangent spline behavior.

Referring next to FIG. 7, a process determines 705 an insertion location on the mesh. For example, a user may select points for the insert ion location on a rendered image mesh with the spline curve. A ray trace is applied 710 to the viewing angle to determine the mesh face at the user indicated location, for example, in the same manner outlined in FIG. 3B. The process iteratively calculates the 715 distance between line segment midpoints and the selected mesh face. The process identifies 720 the line segment with the nearest midpoint to the selected mesh face. Selected line segment is broken and 725 a new control point is inserted at the selected mesh face. Control points are referenced sequentially along a curve (reference denoted as an integer, ‘n’), starting with the first point added at a curve conception. The process reassigns 730 the larger reference value from the broken segment to the inserted control point. Sequentially, further control points are changed 735 to reference n′=n+1, where n corresponds to the index of a control point prior to the addition of the newest point. The curve with the new control point reference scheme is recalculated 740 and the curve is evaluated 745 for conformity to mesh.

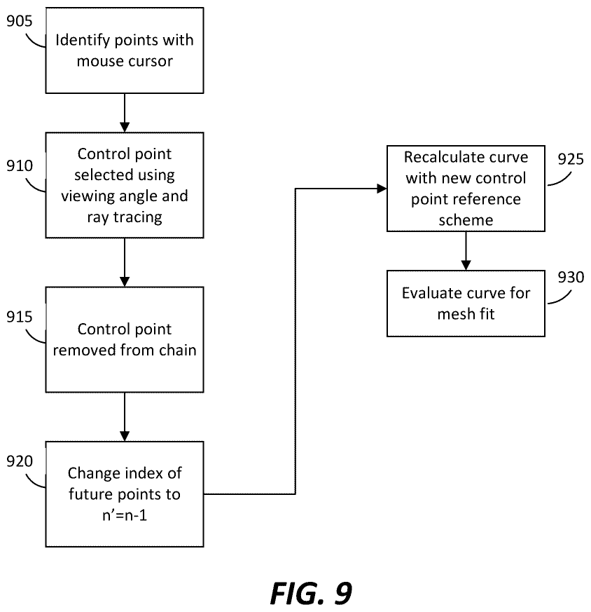

Referring next to FIG. 9, it illustrates an example process for removing points from an existing curve in accordance with an embodiment. The process identifies 905 a control point on the spline curve for deletion. Using a viewing angle and ray tracing, the identified control point is indicated 910 for deletion, for example, by changing a visual characteristic of the point (e.g., change color from white to yellow). The selected control point is deleted and 915 removed from the spline curve. Points sequentially past the deleted control point are 920 re-indexed to n′=n−1. The process re-calculates 925 the spline curve with a new control point reference scheme and evaluates 930 the curve for conformity to mesh.

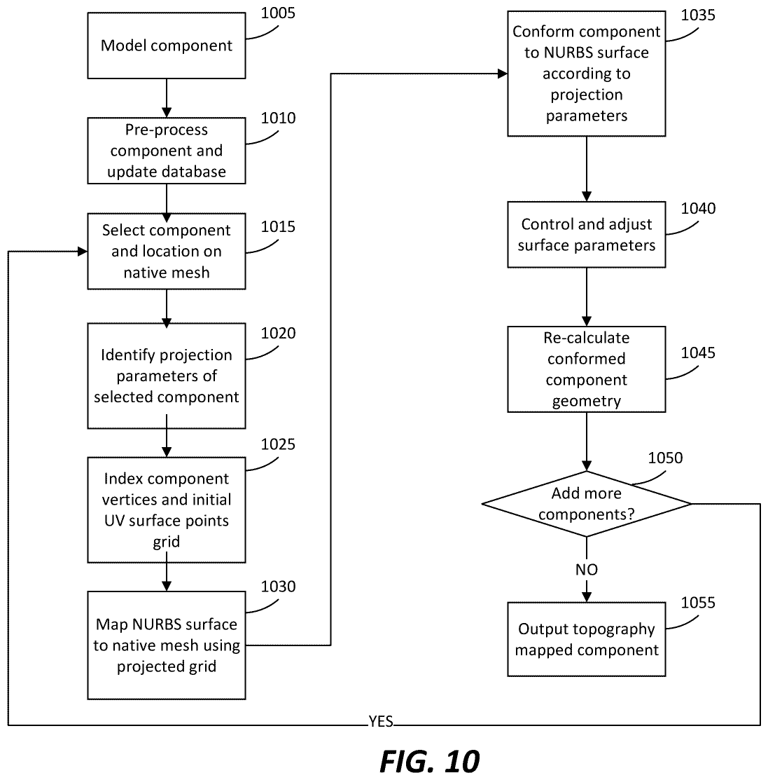

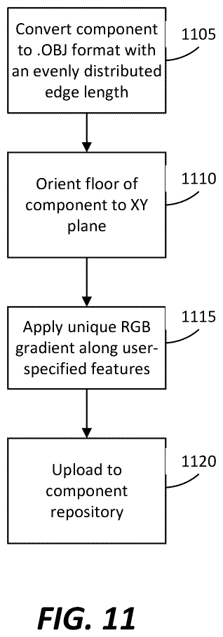

The disclosed configurations may be used to mass customize feature sets of a device (or product) specific to a user anatomy or anatomical part. FIG. 10 illustrates an example process for contouring parametrically modelled components for mass customization in accordance with an embodiment. The process starts with modeling 1005 a component in a development tool such as a computer aided design (CAD) tool. The modeled component is pre-processed 1010 and updated in a repository, e.g., a database. FIG. 11 illustrates an example process for pre-processing to prepare for surface mapping in accordance with an embodiment. The process converts 1105 the modeled component into a geometry format of preferred density (evenly distributed edge length). The floor of the component is oriented 1110 onto the X-Y coordinate plane and centered at the origin. Vertices are colored with an RGB gradient 1115 and the preprocessed component is uploaded to the component registry, e.g., in a database.

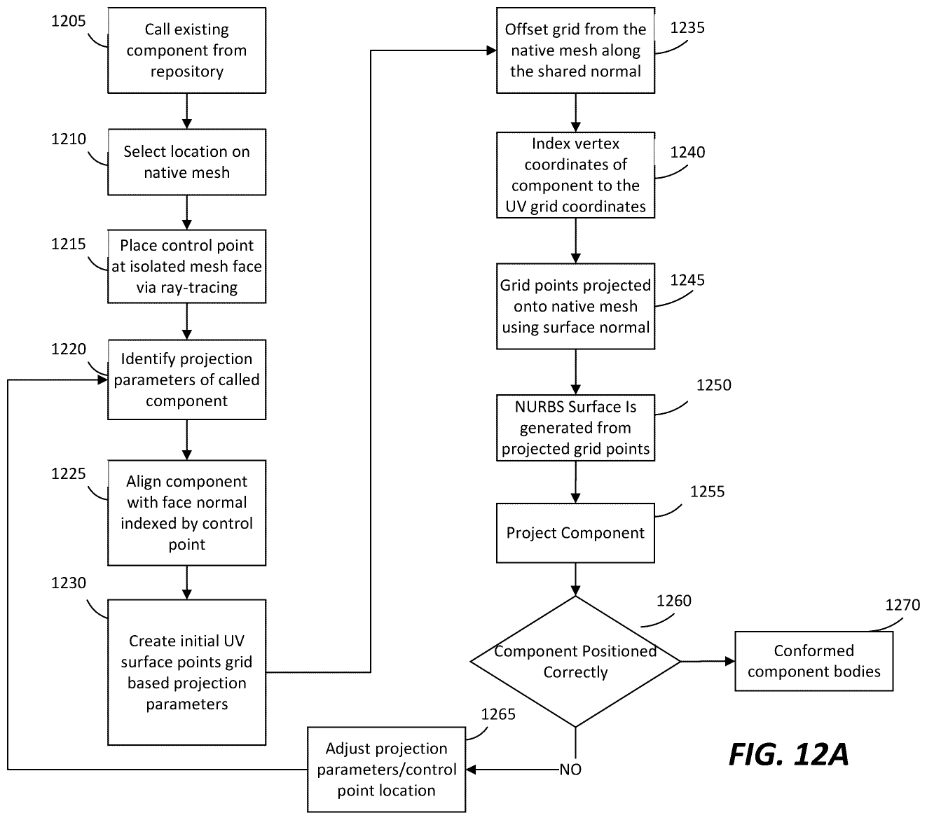

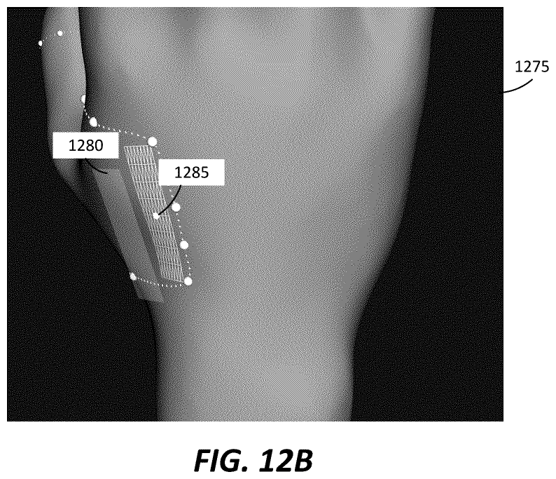

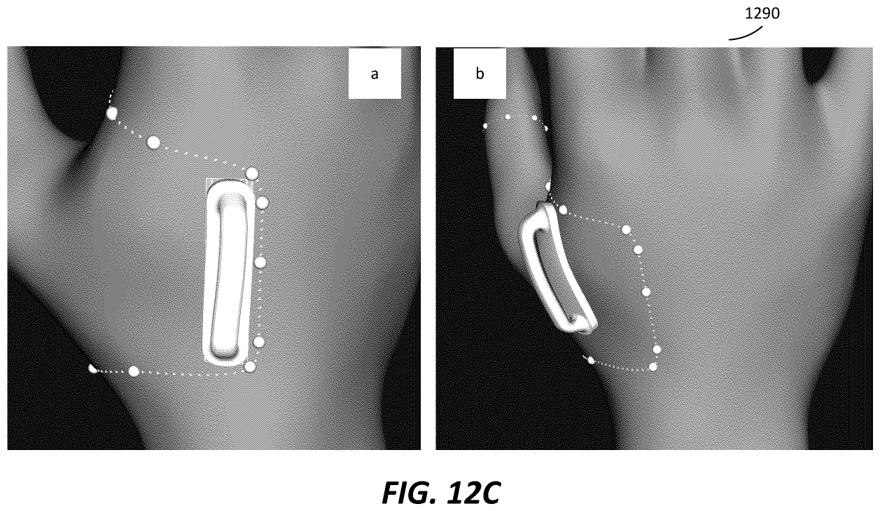

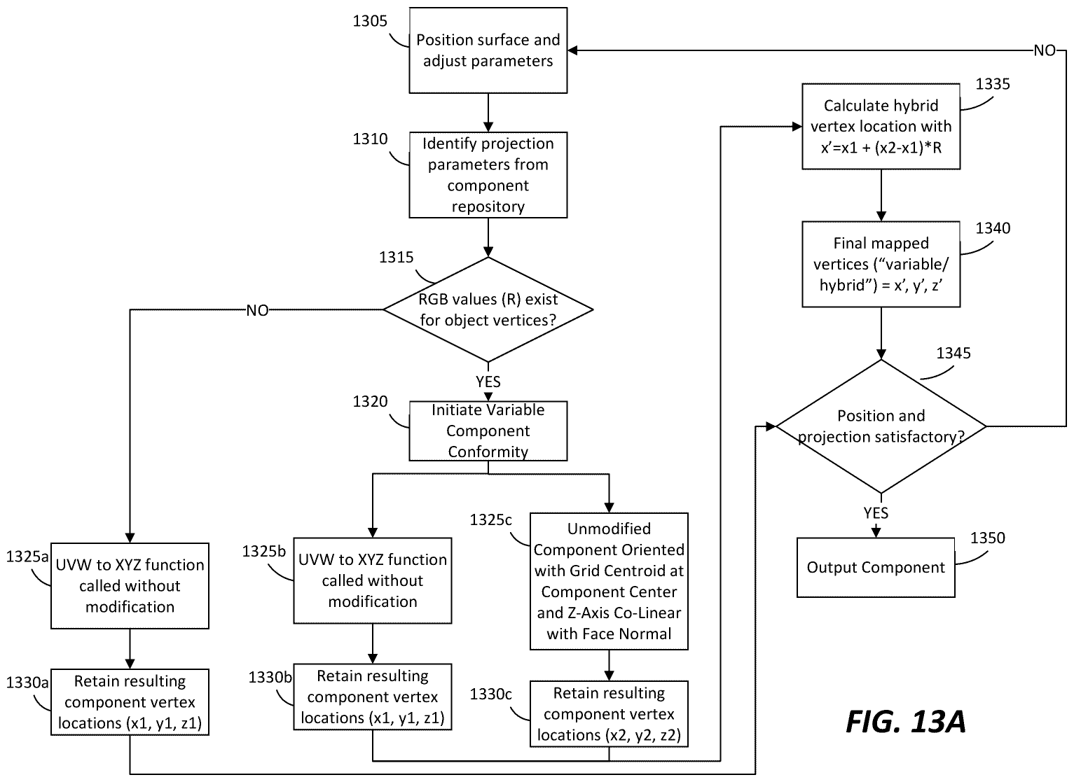

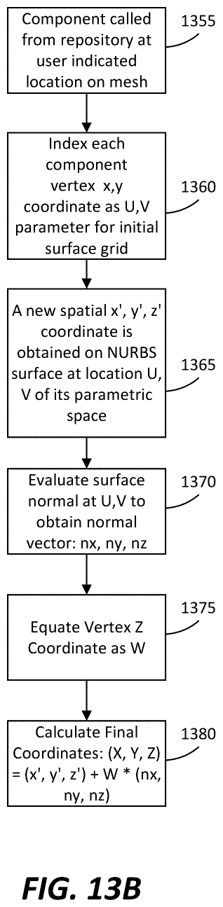

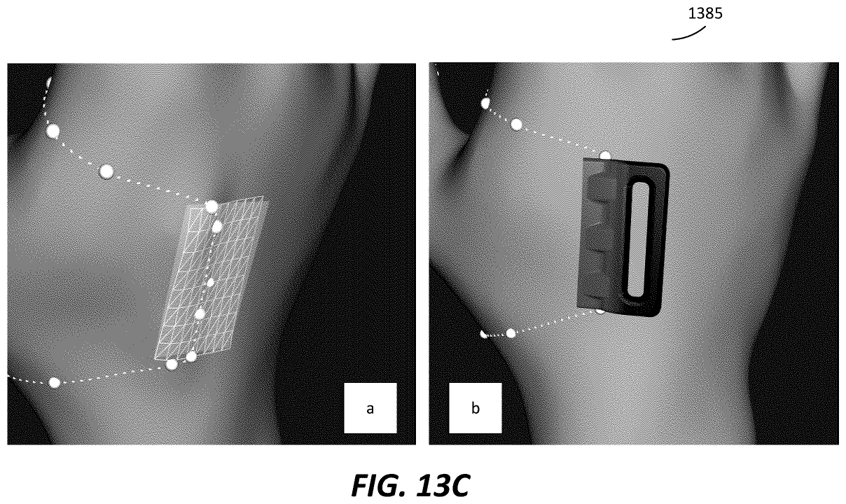

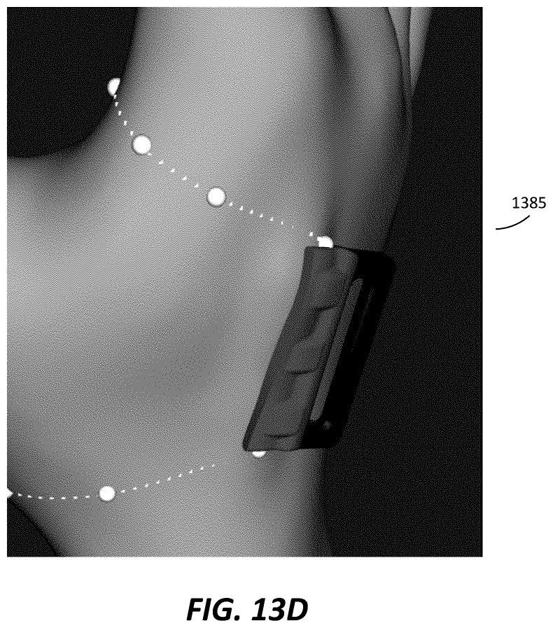

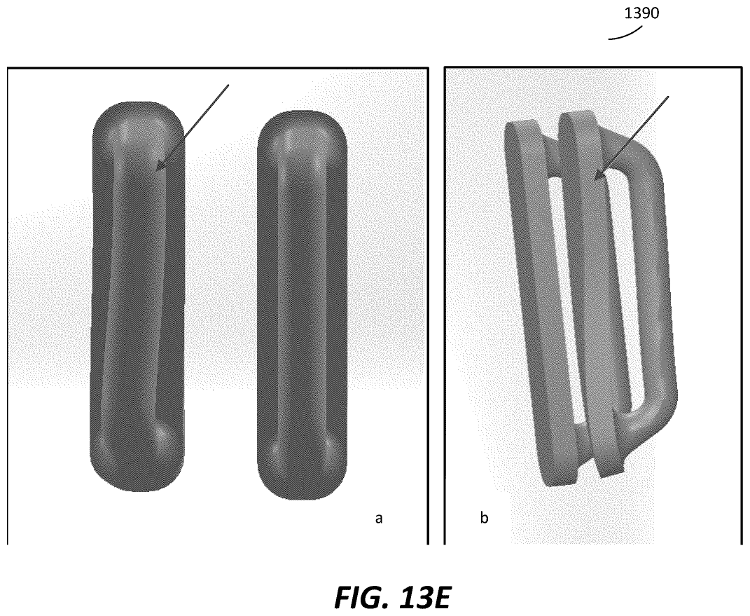

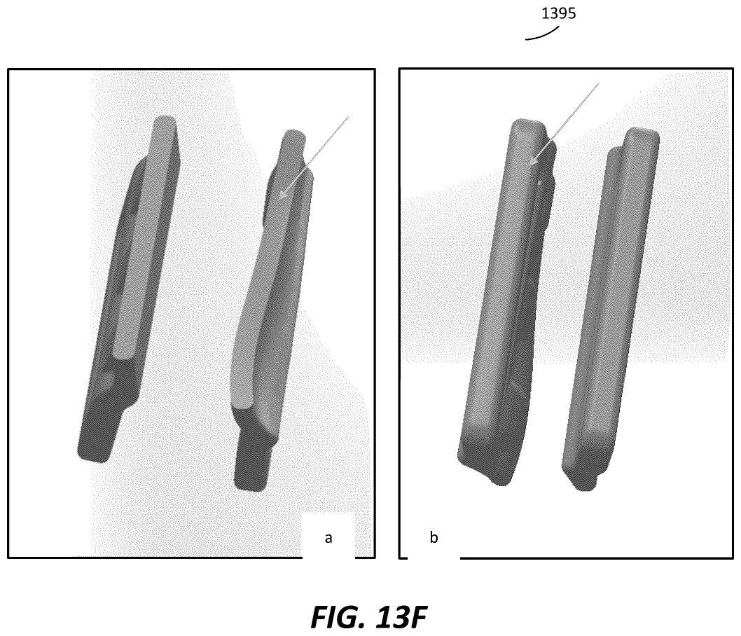

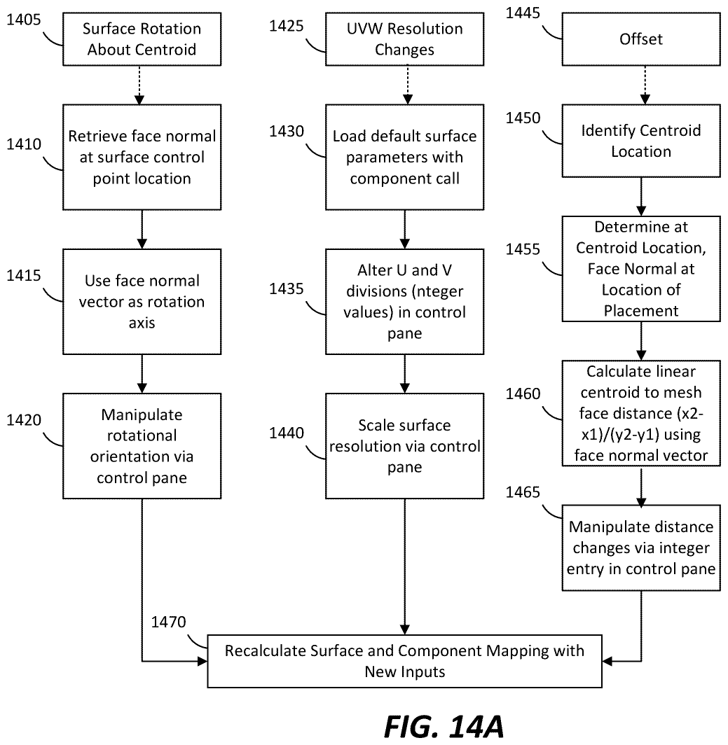

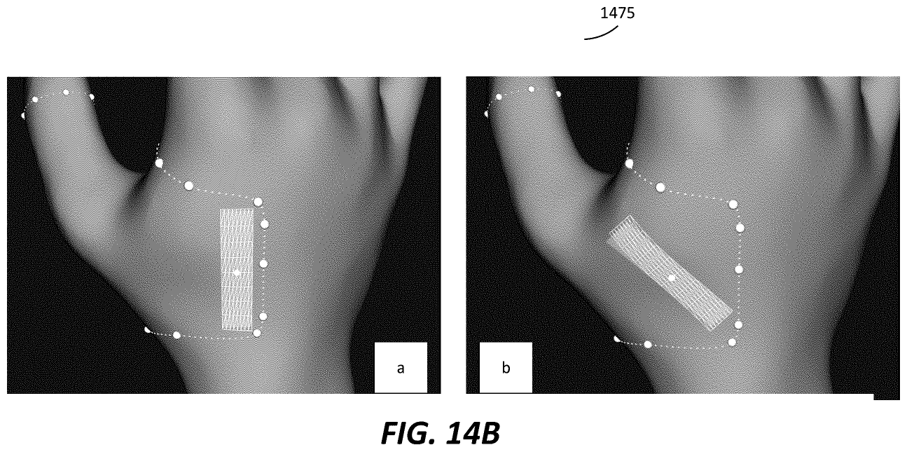

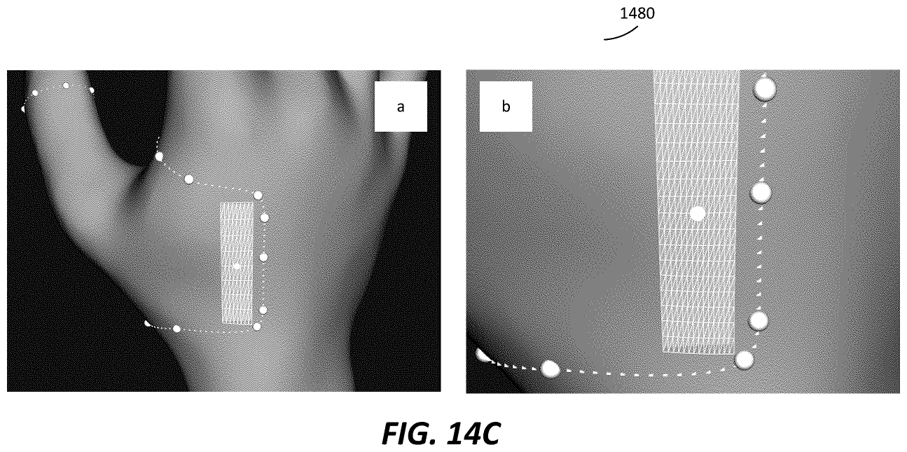

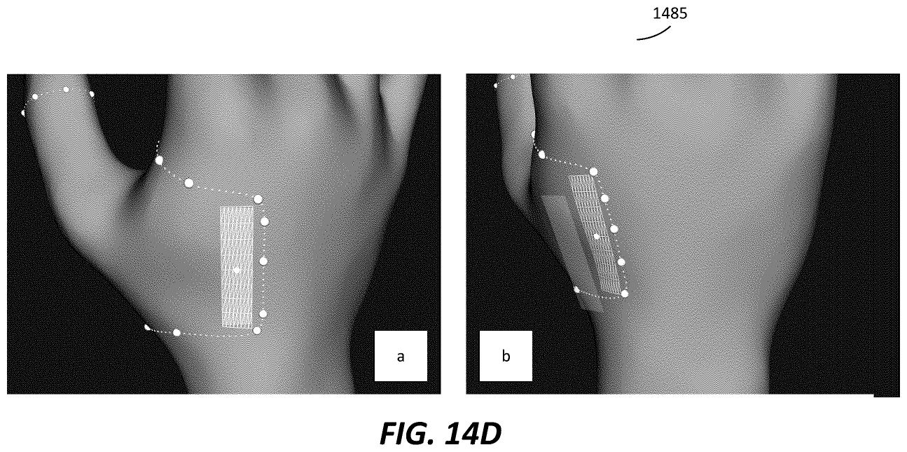

Referring back to FIG. 10. The modeled component may later be selected and/or retrieved 1015, e.g., from the database. The user selects placement 1015 of the component on native mesh using the method outlined in FIG. 3B. The process identifies 1020 component projection parameters as defined by both the user within the environment and the properties of the component as they are output from pre-processing outline in FIG. 11. An initial surface points grid 1025 is oriented to the called component and component vertices are indexed to the UV coordinates of the grid. A NURBS (non-uniform rational basis spline) surface is created 1030 from the projected surface-grid points as is further described below with FIGS. 12A-12C. The component geometry is 1035 projected (mapped) to the NURBS surface according to projection parameters and calculated vectors. The distortion (mapping) process is further described below with FIGS. 13A-13D. NURBS surface parameters are adjusted 1040 as needed and the geometry is re-calculated 1045. For example, the surface and the component are directly paired as complementary features and the surface is manipulated at the control point to move the component. Therefore, these adjustment parameters are rotation, scale, subdivision, and location (on the native mesh) and they influence how that component projects onto the mesh. The adjustment process is further described below with FIGS. 14A-14D. The process determines 1050 whether additional component is to be added to complete the product design 1055. If so, the process returns to selection 1015 of another component. If not, the process outputs an updated, or new, component layout mapped to the native mesh at user specified locations and orientations based on the changes applied. The output may be stored in the database 115.

Reference is now made to FIGS. 12A-12C, which illustrates an example process for component placement and NURBS surface formation on the native mesh in accordance with an embodiment. The process retrieves 1205 an existing modeled component, e.g., from the database 115. A location on an image mesh, e.g., corresponding to an anatomical part, is selected via a pointing device or trackpad 1210 to place the component. A ray trace is applied 1215 to the viewing angle to determine the mesh face at the user indicated location and a surface control point (not bound to profile curves) is placed on the selected mesh face in the same manner outlined in FIG. 3B. The process identifies 1220 projection parameters of called components, for example, as set in the environment and intrinsic within the component resulting from pre-processing, as described with FIG. 11. The component z-axis is aligned 1225 with the face normal indexed by the control point. A grid of UV surface points is calculated based on projection parameters and component geometry. For example the process ensures the grid centroid is mated to the oriented component and coincident with the mesh normal at the control point, axially binding the 3 entities to the native mesh. The process offsets the grid 1235 along the referenced native mesh normal in accordance to user-defined and intrinsic projection parameters for the called component. Component vertices are indexed to the UV grid 1240 and retained for projection further outlined in FIGS. 13A-13F. The surface points grid is projected 1245 onto the native mesh at face intersections in a method similar to that of FIG. 3B and a NURBS surface is generated 1250 from the projected grid points. The component vertices are projected onto the NURBS surface 1255 as indicated by projection parameters and further outlined in FIGS. 13A-F. The process enables the user to alter surface characteristics 1265 until the desired result is obtained as further outlined below in FIG. 14. If the process determines the surface has been formatted correctly on the native mesh, the conformed component body is retained for final device Boolean.

FIG. 12B is an image 1275 that illustrates an example of the surface mapping process described above. The initial UV surface-points grid 1280, in this case a plane, is seen offset from the native mesh before projecting downward in the direction of the face normal identified with the control point 1285. This pre-projected UV coordinate system is equated to the called component's XYZ coordinate system, which will serve as a baseline for component transformation below. The NURBS surface 1280 (wireframe) is mapped onto the native mesh showing conformity to the mesh surface. FIG. 12C 1290 illustrates how this sequence is utilized to project and distort a 3D component to the mesh surface, discussed in more detail below.

FIGS. 13A through 13E illustrate an example process of variable component conformity to native mesh in accordance with an embodiment. Specifically, the process determines the degree to which the vertices of a component will distort from their original, relative XYZ coordinate locations assigned in pre-processing (e.g., as described with FIG. 11) as they are transformed to UVW coordinates of the projected NURBS surface and therefore into new global XYZ coordinates. Continuing from the output of FIGS. 12A through 12C whereby a component was called and a NURBS surface positioned on the native mesh, surface position and parametric adjustments 1305 are made as needed for proper placement. These processes outlined in more detail in FIGS. 14A-14D.

Referring briefly to FIGS. 14A through 14D, illustrated are example processes for surface parameter control and parametric adjustments in accordance with an embodiment. For example, for surface rotation about a centroid 1405 is illustrated with FIG. 14B. The process references a face normal at the mesh face location of a control point on the native mesh as described above (for example, as described with FIG. 12A). The process for surface rotation about a centroid retrieves 1410 a face normal at a surface control point location. A face normal vector is used 1415 as a rotation axis. The rotational orientation is manipulated 1420 via a control pane. The manipulated rotational orientation is used for recalculating the 1470 the projected NURBS surface and resultant component projection.

The UV resolution changes 1425 are illustrated with, for example, the image 1480 of FIG. 14C. The process loads 1430 default surface parameters with a component call. U and V divisions (integer values) are altered 1435 in the control plane. The surface resolution is scaled 1440 by updating the numbers of rows and columns of its grid points. The scaled surface resolution is input used for recalculating 1470 the projected NURBS surface and resultant component projection.

An offset of the surface grid points prior to projection 1445 is illustrated with, for example, the image 1485 of FIG. 14D. The process identifies 1450 the location of the centroid as described above (for example, as described with FIG. 12A). The process determines 1455, at the centroid location, the face normal at a location of placement. The process calculates 1460 a linear centroid to mesh face distance (x2−x1/y2−y1), where x1, x2, y1, y2 are coordinates in the X-Y plane of the pre-projected surface points grid, using a face normal vector. The process manipulates 1465 distance value via numerical entry in the control pane, ultimately adjusting the ‘W’ value in the projection equation outlined in FIG. 13B. The manipulated offset changes are also input for recalculating 1470 the projected NURBS surface and resultant component projection. The re-calculations mentioned above are as described above (for example, as described with FIG. 12A) and below (for example, as described with FIG. 13A).

With the surface position and parametric adjustments made, reference is made back to FIG. 13A. The process continues with identifying 1310 projection parameters from the component repository database and from within the user-controlled environment. The process determines 1315 if RGB variables exist for object vertices of the component. If not, component projection/mapping proceeds using a standard 1325 UVW to XYZ transformation outlined in FIG. 13B. Component vertices are indexed 1360 by equating vertex x, y (local to the component) coordinates to the relative U, V coordinates of the mapped surface points grid. A new spatial x′, y′, z′ coordinate is obtained 1365 on the projected NURBS surface location at U, V of its parametric space. The surface normal is evaluated to obtain 1370 normal vector nx, ny, nz and the final Z coordinate for each vertex is 1375 equated as W. The process calculates final, projected, and mapped vertex coordinates. The final coordinates X, Y, Z may be calculated 1380 with: (X, Y, Z)=(x′, y′, z′)+W*(nx, ny, nz), reflecting a uniform transformation of each vertex relative to the projected NURBS surface. FIG. 12C illustrates a component projected to an irregular native mesh using an unmodified UVW-XYZ transformation wherein all vertices have shifted relative to one another to globally deform the component.

Continuing with FIG. 13A, if RGB variable exists for object vertices, the process initiates 1320 a variable component conformity using a modified UVW-XYZ transformation. Here, the component undergoes dual surface projections. A first calculates 1325b an unmodified UVW-XYZ transformation as outlined above. Here, the component vertex locations of the unmodified transformation (x1, y1, z1) are retained 1330. In parallel, a second process keeps the component origin (centroid of surface points grid) fixed against the selected mesh face (control point), keeping original vertex relations intact and retaining component vertex locations (x2, y2, z2) 1330b. The result is a component resting on the native mesh at the control point without distortion. A “hybrid” or location for each vertex is calculated as a function 1335 of the RGB multiplier (denoted as R) inherent in the pre-processed component. R values range from 0-1, with 1 allowing the maximal vertex movement to the projected surface corresponding to x1, y1, z1 and 0 allowing no vertex movement corresponding to x2, y2, z2. A hybrid vertex location with x′=x1+ (x2−x1)*R is calculated (and repeated for y, z coordinates) 1335. The process maps 1340 the final vertices (variable hybrid) as (=to) x′, y′, z′. FIG. 13C and FIG. 13D illustrate a component with an RGB gradient that has undergone variable conformity. Here, a value of 1 (fully RED) projects according to a full UVW-XYZ transformation as did the entire component in FIG. 12C. The vertices with an R value of 0 do not conform and retain their position as if the component centroid was made coincident with the control point. Mid-values conform proportionately per the equation noted above.

The process determines 1345 if the component position and projection are satisfactory. If not, the process returns to the surface re-positioning and parametric adjustment 1305. If it is satisfactory, the process outputs 1350 a component that may be stored in a database, e.g., 115, which may be retrievable for manufacturing by the manufacturing system 125 and prepared for the Boolean chain, an operation for merging and subtracting mesh bodies from one another 165. The final component vertices are rendered in the environment. FIGS. 13E-13F compare differences in part geometry based on conformity/transformation method. In FIG. 13E 1390, the standard projection method is used (red arrow) and shows differences with the original component as designed in traditional CAD. In FIG. 13F 1395, the variable conformity method was used (yellow arrows in (a) and (b)) and shows differences with the original component as designed in traditional CAD, specifically how the edges in panel a distorted after the transformation, whereas the edges of panel b did not.

If the RGB variables do not exist the process retains 1315 component vertices locations (x1, y1, z1) and determines 1345 if the position and projection are satisfactory. If not, the process returns to the surface positions and parametric adjustment 1305. If it is satisfactory, the process outputs 1350 a component that may be stored in a database, e.g., 115, which may be retrievable for manufacturing by the manufacturing system 125.

Referring back to FIG. 12A, with the component projected 1255 according to the parameters and rendering on the mesh, the surface parameters may be optionally manipulated 1265. The process determines 1260 if the surface and component (device) are positioned correctly on the mesh. If not, the surface parameters may be further manipulated 1265. If the mesh surface parameters are properly positioned, the component (device) is configured to the properly projected 1270. FIG. 12C illustrates components considered in this example to be properly positioned as seen in a first view 1270a and a second view 1270b. The projections of FIG. 13A will recalculate and render with each adjustment to the underlying surface. This view may be stored in a file in a database, e.g., database 115.

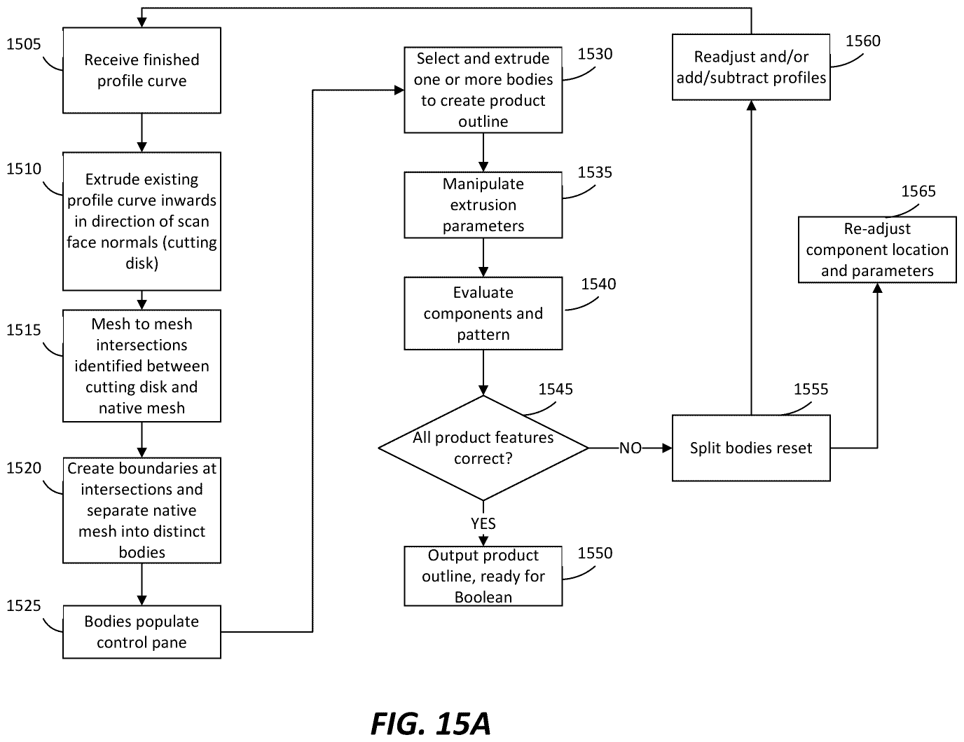

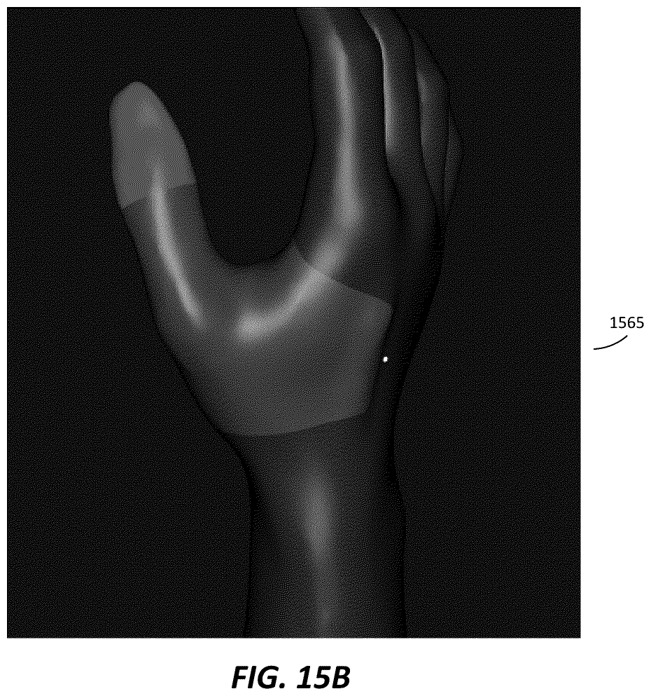

With the various profile curves and conformed components created from the processes described, the process is applied to realize the final device for manufacturing. Turning now to FIGS. 15A and 15B, illustrated is an example process for product body formation via a profile curve driven splitting of the native mesh in accordance with an embodiment. The process receives 1505 finished profile curves, for example, from a storage repository (e.g., database). The finished profile curves may be as described above (for example, as described with FIG. 2). The process extrudes 1510 existing profile curves inward in the direction of scan face normals via cutting disks. Mesh intersections are identified 1515 between the cutting disk and native mesh. For example a line is extruded to intersect the mesh. The intersections create 1520 boundaries and separate native mesh into distinct surface bodies. FIG. 15B illustrates a hand 1565 of a native mesh split into surface bodies by the profile curve boundaries. The bodies populate 1525 a control pane, which enables user selection and manipulation of extrusion parameters.

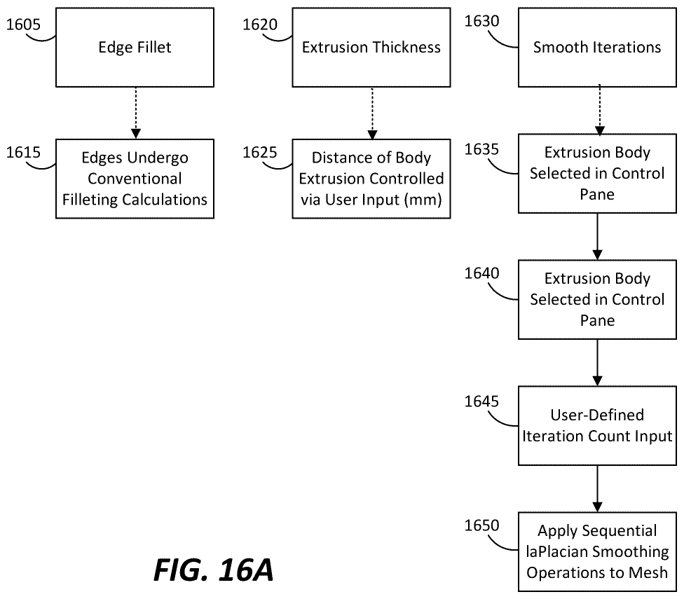

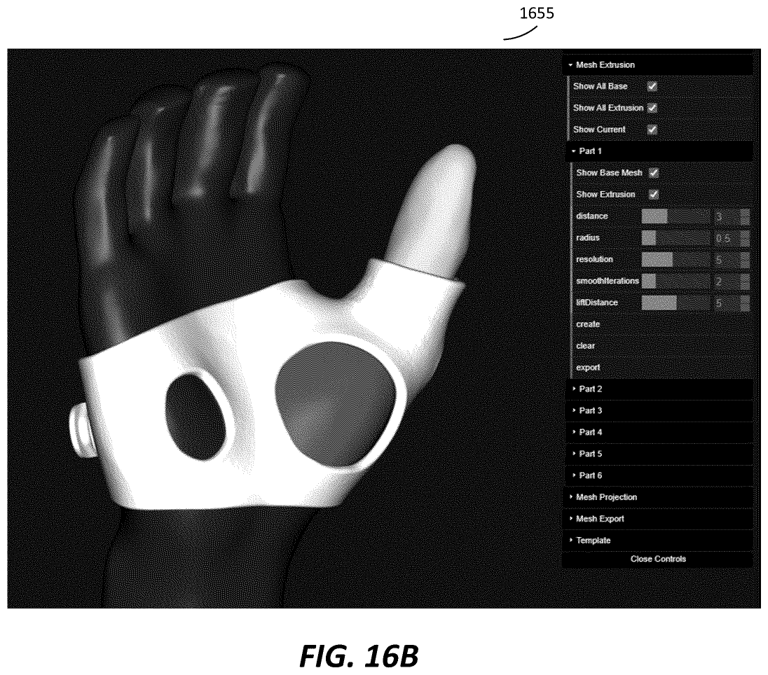

One or more bodies may be selected 1530 to create a product outline or multiple product outlines. The product parameters may be manipulated 1535. FIG. 16A illustrates example user-controlled extrusion parameters available for each surface body resulting from the 1565 split bodies. The parameters include, for example, edge fillet 1605, which undergo 1610 conventional filleting techniques. Another parameter is extrusion thickness 1620, which is the distance 1620 of body extrusion controlled. Another parameter is smooth iterations 1630, which may be LaPlacian smoothing 1635 operations and control of iteration counts. FIG. 16B illustrates product designed with multiple, overlapping surface. Surfaces bound within other surfaces can be omitted from extrusion 1530 to form 1655 window/cutouts, or given alternate extrusion parameters to create localized regions of differential extrusion thickness.

Returning back to FIG. 15A, the process determines if the 1540 component, pattern, profile, and extrusion parameters are collectively acceptable for the final design. If not, the split bodies are reset 1555. The profiles are readjusted or are added or subtracted 1560. 1565 Components and patterns are added, removed, and/or adjusted as needed. The process returns to receiving 1505 another set of finished profile curves. If the profile is correct, the collective product feature set (extrusion, projected components, pattern) 1560 and is ready for the Boolean chain, whereby all mesh bodies (components, extrusions, patterns) will be combined with the appropriate combination of union, intersection, and subtraction operations. The result of this operation is considered the completed device, saved into a database and ready for manufacturing.

### Computing Machine Architecture

Turning now to FIG. 17, illustrated is an example machine to read and execute computer readable instructions, in accordance with an embodiment. Specifically, FIG. 17 shows a diagrammatic representation of the data processing service 102 (and/or data processing system) in the example form of a computer system 1700. The computer system 1700 is structured and configured to operate through one or more other systems (or subsystems) as described herein. The computer system 1700 can be used to execute instructions 1724 (e.g., program code or software) for causing the machine (or some or all of the components thereof) to perform any one or more of the methodologies (or processes) described herein. In executing the instructions, the computer system 1700 operates in a specific manner as per the functionality described. The computer system 1700 may operate as a standalone device or a connected (e.g., networked) device that connects to other machines. In a networked deployment, the machine may operate in the capacity of a server machine or a client machine in a server-client network environment, or as a peer machine in a peer-to-peer (or distributed) network environment.

The computer system 1700 may be a server computer, a client computer, a personal computer (PC), a tablet PC, a smartphone, an internet of things (IoT) appliance, a network router, switch or bridge, or other machine capable of executing instructions 1724 (sequential or otherwise) that enable actions as set forth by the instructions 1724. Further, while only a single machine is illustrated, the term “machine” shall also be taken to include any collection of machines that individually or jointly execute instructions 1724 to perform any one or more of the methodologies discussed herein.

The example computer system 700 includes a processing system 1702. The processor system 1702 includes one or more processors. The processor system 1702 may include, for example, a central processing unit (CPU), a graphics processing unit (GPU), a digital signal processor (DSP), a controller, a state machine, one or more application specific integrated circuits (ASICs), one or more radio-frequency integrated circuits (RFICs), or any combination of these. The processor system 1702 executes an operating system for the computing system 1700. The computer system 1700 also includes a memory system 1704. The memory system 1704 may include or more memories (e.g., dynamic random access memory (RAM), static RAM, cache memory). The computer system 1700 may include a storage system 1716 that includes one or more machine readable storage devices (e.g., magnetic disk drive, optical disk drive, solid state memory disk drive).

The storage unit 1716 stores instructions 1724 (e.g., software) embodying any one or more of the methodologies or functions described herein. For example, the instructions 1724 may include instructions for implementing the functionalities of the transaction module 330 and/or the file management module 335. The instructions 1724 may also reside, completely or at least partially, within the memory system 1704 or within the processing system 1702 (e.g., within a processor cache memory) during execution thereof by the computer system 700, the main memory 1704 and the processor system 1702 also constituting machine-readable media. The instructions 1724 may be transmitted or received over a network 1726, such as the network 1726, via the network interface device 1720.

The storage system 1716 should be taken to include a single medium or multiple media (e.g., a centralized or distributed database, or associated caches and servers communicatively coupled through the network interface system 1720) able to store the instructions 1724. The term “machine-readable medium” shall also be taken to include any medium that is capable of storing instructions 724 for execution by the machine and that cause the machine to perform any one or more of the methodologies disclosed herein. The term “machine-readable medium” includes, but not be limited to, data repositories in the form of solid-state memories, optical media, and magnetic media.

In addition, the computer system 1700 can include a display system 1710. The display system 1710 may driver firmware (or code) to enable rendering on one or more visual devices, e.g., drive a plasma display panel (PDP), a liquid crystal display (LCD), or a projector. The computer system 1700 also may include one or more input/output systems 1712. The input/output (IO) systems 1712 may include input devices (e.g., a keyboard, mouse (or trackpad), a pen (or stylus), microphone) or output devices (e.g., a speaker). The computer system 1700 also may include a network interface system 1720. The network interface system 1720 may include one or more network devices that are configured to communicate with an external network 1726. The external network 1726 may be a wired (e.g., ethernet) or wireless (e.g., WiFi, BLUETOOTH, near field communication (NFC)).

The processor system 1702, the memory system 1704, the storage system 1716, the display system 1710, the IO systems 1712, and the network interface system 1720 are communicatively coupled via a computing bus 1708.

### Additional Configuration Considerations

The disclosed configurations beneficially provide for a more time and computationally efficient design process. The method of applying profile curves with a high ratio of interpolated points to control points allows for accurate, adjustable spline mapping to complex anatomy at improved speed, allowing users to iterate quickly between designs on any mesh. The projection method of components via variable component conformity allows dimensioned components designed in traditional parametric CAD to be accurately projected to complex mesh surfaces while preserving key relations between features. The added projection stability allows preservation of interfacing or otherwise dimensionally delicate geometries without the need to build on the mesh directly.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of components, modules, or mechanisms. Modules may constitute either software modules (e.g., code embodied on a machine-readable medium and processor executable) or component modules. A component module is tangible unit capable of performing certain operations and may be configured or arranged in a certain manner. In example embodiments, one or more computer systems (e.g., a standalone, client or server computer system) or one or more component modules of a computer system (e.g., a processor or a group of processors) may be configured by software (e.g., an application or application portion) as a component module that operates to perform certain operations as described herein.

In various embodiments, a component module may be implemented mechanically or electronically. For example, a component module is a tangible component that may comprise dedicated circuitry or logic that is permanently configured (e.g., as a special-purpose processor, such as a field programmable gate array (FPGA) or an application-specific integrated circuit (ASIC)) to perform certain operations. A component module may also comprise programmable logic or circuitry (e.g., as encompassed within a general-purpose processor or other programmable processor) that is temporarily configured by software to perform certain operations. It will be appreciated that the decision to implement a component module mechanically, in dedicated and permanently configured circuitry, or in temporarily configured circuitry (e.g., configured by software) may be driven by cost and time considerations.

The performance of certain of the operations may be distributed among the one or more processors, not only residing within a single machine, but deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

Upon reading this disclosure, those of skill in the art will appreciate still additional alternative structural and functional designs for a system and a process for native surface extrapolation through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

What is claimed is:

1. A method for enabling variable component conformity to native mesh, comprising:
receiving surface position and parametric adjustment parameters for an image mesh;
identifying projection parameters for a component from a component repository;
initiating variable component conformity in response to existence of RGB variables for object vertices;
placing a control point location on the image mesh;
pairing a control point location with a centroid of a surface and equating to a first coordinate system and a second coordinate system, each coordinate system retaining component vertices locations as a first set of coordinates;
identifying, for each vertex, an RGB value;
calculating a hybrid vertex location using RGB value by:
equating the first set of coordinates from the first coordinate system with the first set of coordinates from the second coordinate system, and
adjusting an offset value with an RGB value;
generating a new set of coordinates in the second coordinate system;
generating mapped vertices from the hybrid vertex location; and
generating an output for the component.

2. The method of claim 1, wherein the surface is a NURBS surface.

3. The method of claim 2, wherein the first coordinate system is a UVW coordinate system and the second coordinate system is a XYZ coordinate system.

4. The method of claim 3, wherein the RGB value is an R coefficient.

5. The method of claim 4, wherein the offset value is an initial distance of a vertex along a Z-axis in the XYZ coordinate system.

6. The method of claim 1, further comprising retaining component vertices locations in response to nonexistence of RGB variables for object vertices.

7. The method of claim 2, wherein the hybrid vertex location is calculated as a variable location for each vertex as a function of the RGB value.

8. A non-transitory computer readable storage medium comprising stored instructions to enable a variable component conformity to native mesh, the instructions when executed causing a processing system to:
receive surface position and parametric adjustment parameters for an image mesh;
identify projection parameters for a component from a component repository;
initiate variable component conformity in response to existence of RGB variables for object vertices;
place a control point location on the image mesh;
pair a control point location with a centroid of a surface and equating to a first coordinate system and a second coordinate system, each coordinate system retaining component vertices locations as a first set of coordinates;
identify, for each vertex, an RGB value;
calculate a hybrid vertex location using RGB value by:
equating the first set of coordinates from the first coordinate system with the first set of coordinates from the second coordinate system, and
adjusting an offset value with an RGB value;
generate a new set of coordinates in the second coordinate system;
generate mapped vertices from the hybrid vertex location; and
generate an output for the component.

9. The non-transitory computer readable storage medium of claim 8, wherein the surface is a NURBS surface.

10. The non-transitory computer readable storage medium of claim 9, wherein the first coordinate system is a UVW coordinate system and the second coordinate system is a XYZ coordinate system.

11. The non-transitory computer readable storage medium of claim 10, wherein the RGB value is an R coefficient.

12. The non-transitory computer readable storage medium of claim 11, wherein the offset value is an initial distance of a vertex along a Z-axis in the XYZ coordinate system.

13. The non-transitory computer readable storage medium of claim 8, further comprising instructions that when executed causes the processing system to retain component vertices locations in response to nonexistence of RGB variables for object vertices.

14. The non-transitory computer readable storage medium of claim 9, wherein the instructions to calculate the hybrid vertex location further comprises instructions that when executed causes the processing system to calculate a variable location for each vertex as a function of the RGB value.

15. A system comprising a processing system comprising one or more processors;
a non-transitory computer readable storage medium, coupled with the processing system, and comprising stored instructions to enable a variable component conformity to native mesh, the instructions when executed causing a processing system to:
receive surface position and parametric adjustment parameters for an image mesh;
identify projection parameters for a component from a component repository;
initiate variable component conformity in response to existence of RGB variables for object vertices;
place a control point location on the image mesh;
pair a control point location with a centroid of a surface and equating to a first coordinate system and a second coordinate system, each coordinate system retaining component vertices locations as a first set of coordinates;
identify, for each vertex, an RGB value;
calculate a hybrid vertex location using RGB value by:
equating the first set of coordinates from the first coordinate system with the first set of coordinates from the second coordinate system, and
adjusting an offset value with an RGB value;
generate a new set of coordinates in the second coordinate system;
generate mapped vertices from the hybrid vertex location; and
generate an output for the component.

16. The system of claim 15, wherein the surface is a NURBS surface.

17. The system of claim 16, wherein the first coordinate system is a UVW coordinate system, the second coordinate system is a XYZ coordinate system, and the RGB value is an R coefficient.

18. The system of claim 17, wherein the offset value is an initial distance of a vertex along a Z-axis in the XYZ coordinate system.

19. The system of claim 15, further comprising instructions that when executed causes the processing system to retain component vertices locations in response to nonexistence of RGB variables for object vertices.

20. The system of claim 16, wherein the instructions to calculate the hybrid vertex location further comprises instructions that when executed causes the processing system to calculate a variable location for each vertex as a function of the RGB value.
